(19) United States
(12) Patent Application Publication
(10) Pub. No.: US 2026/0123336 A1
(43) Pub. Date: Apr. 30, 2026

(54) SENSOR DEVICE

(71) Applicant: Samsung Electronics Co., Ltd., Suwon-si (KR)

(72) Inventors: Jongmin SONG, Suwon-si (KR); Younsok CHOI, Suwon-si (KR); Juhyun KIM, Suwon-si (KR); Byoung Min YUN, Suwon-si (KR); Hohyun LEE, Suwon-si (KR)

(73) Assignee: Samsung Electronics Co., Ltd., Suwon-si (KR)

(21) Appl. No.: 19/200,950

(22) Filed: May 7, 2025

(30) Foreign Application Priority Data
Oct. 30, 2024 (KR) 10-2024-0150714

(51) Int. Cl. H01L 21/67; G01L 11/00; G01P 5/10

(52) U.S. Cl. CPC H10P 72/0604; G01L 11/002; G01P 5/10

(57) ABSTRACT

Provided is a sensor device disposed in a semiconductor manufacturing apparatus, the sensor device including a sensor array configured to be in a flow path of a gas supplied to the semiconductor manufacturing apparatus, the sensor array including a first calorimeter and a second calorimeter, and a controller configured to identify a pressure of the gas based on a temperature of the first calorimeter, an ambient temperature, and a first amount of heat transfer in the first calorimeter, and identify a flow velocity of the gas based on a temperature of the second calorimeter, the ambient temperature, a second amount of heat transfer in the second calorimeter, and the pressure.

### CROSS-REFERENCE TO RELATED APPLICATIONS

This application claims the benefit of Korean Patent Application No. 10-2024-0150714, filed on Oct. 30, 2024, in the Korean Intellectual Property Office, the disclosure of which is incorporated herein by reference in its entirety.

### BACKGROUND

Example embodiments relate to an electronic apparatus, and more particularly, a sensor device.

A semiconductor manufacturing apparatus (or semiconductor manufacturing equipment) may perform one or more various semiconductor processes such as chemical vapor deposition (CVD) processes and/or etching processes to manufacture a semiconductor device.

Semiconductor processes require precise environment control. A sensor device may monitor, in real time, an internal environment of the semiconductor manufacturing apparatus performing a semiconductor process. In CVD processes and etching processes, the flux or flow of reactive and/or non-reactive gases may have direct influence on the quality and/or productivity of the corresponding process. The flow of gases may be difficult to measure compared to other physical quantities. Estimating and verifying the flow of gases through a simulation or via trial and error has low efficiency in terms of time and/or costs. In addition, when a condition of the semiconductor processes and/or the semiconductor manufacturing apparatus changes, it may be advantageous to generate a new verification and/or estimation of the gas flow profiles. Accordingly, a manner for accurately and efficiently measuring the flow of gases within a semiconductor manufacturing apparatus is proposed.

### SUMMARY

Some example embodiments the present disclosure provide a sensor device that monitors an internal environment of a semiconductor manufacturing apparatus.

Example embodiments are not limited to the technical features described above, and other technical features may be inferred from the example embodiments below.

According to some example embodiments, there is provided a sensor device for use in a semiconductor manufacturing apparatus, the sensor device including a sensor array configured to be in a flow path of a gas supplied to the semiconductor manufacturing apparatus, the sensor array including a first calorimeter and a second calorimeter, and a controller configured to identify a pressure of the gas based on a temperature of the first calorimeter, an ambient temperature, and a first amount of heat transfer in the first calorimeter, and identify a flow velocity of the gas based on a temperature of the second calorimeter, the ambient temperature, a second amount of heat transfer in the second calorimeter, and the pressure.

According to some example embodiments, there is provided a sensor device for use within a semiconductor manufacturing apparatus to which a gas is supplied, the sensor device including a sensor array including a first calorimeter, a second calorimeter, and an insulation material configured to cover the first calorimeter, and a controller configured to identify a first amount of heat transfer in the first calorimeter and a second amount of heat transfer in the second calorimeter, generate a corrected second amount by correcting the second amount of heat transfer based on a difference value between the first amount of heat transfer and the second amount of heat transfer, and identify a flow velocity of a gas based on the corrected second amount of heat transfer, a temperature of the second calorimeter, an ambient temperature, and a pressure of the gas.

According to some example embodiments, there is provided a sensor device for use within a semiconductor manufacturing apparatus to which a gas is supplied, the sensor device including a substrate including a plurality of support parts, a plurality of sensor arrays on the plurality of support parts, each of the plurality of sensor arrays including a first pipeline configured to define a flow path in a first direction, a first calorimeter within the first pipeline, a second pipeline configured to define a flow path in a second direction, the second direction different from the first direction, and a second calorimeter within the second pipeline, and a controller configured to identify a flow velocity in the first direction based on a temperature of the first calorimeter, an ambient temperature, a first amount of heat transfer, and a pressure of the gas, identify a flow velocity in the second direction based on a temperature of the second calorimeter, the ambient temperature, a second amount of heat transfer, and the pressure of the gas, and generate a flow velocity map based on the flow velocity in the first direction and the flow velocity in the second direction for a location of each of the plurality of sensor arrays.

According to some example embodiments, a method of measuring gas flows in a semiconductor manufacturing apparatus, the method comprising placing a target substrate including a sensor into a chamber of the semiconductor manufacturing apparatus, supplying a gas into the chamber by a gas supply part, measuring a flow velocity of the gas in the chamber by the sensor. The sensor includes a sensor array configured to be in a flow path of a gas supplied to the semiconductor manufacturing apparatus, the sensor array including a first calorimeter and a second calorimeter; and a controller configured to identify a pressure of the gas based on a temperature of the first calorimeter, an ambient temperature, and a first amount of heat transfer in the first calorimeter, and identify a flow velocity of the gas based on a temperature of the second calorimeter, the ambient temperature, a second amount of heat transfer in the second calorimeter, and the pressure.

According to some example embodiments, the method may further include generating a flow velocity map of the gas in the chamber. The flow velocity map including at least one flow velocity and movement direction of the gas at a given location.

Details of non-limiting example embodiments are included in the detailed description and drawings.

According to some example embodiments, it may be advantageous to provide a sensor device that monitors an internal environment of a semiconductor manufacturing apparatus.

The sensor device according to some example embodiments may accurately and/or efficiently monitor a flow velocity of a gas.

The sensor device according to some example embodiments may monitor a flow velocity of a gas while reducing and/or minimizing an influence of a pressure of the gas.

The sensor device according to some example embodiments may monitor a flow velocity of a gas while reducing and/or minimizing an amount of heat transfer by conduction.

The sensor device according to some example embodiments may monitor a flow velocity and direction of a gas for a semiconductor process at multiple measurement locations on a target substrate.

Effects of the described example embodiments are not limited to those described above, and other effects not mentioned herein may be clearly understood by those skilled in the art from the appended claims.

### BRIEF DESCRIPTION OF THE FIGURES

These and/or other aspects, features, and advantages of the example embodiments will become apparent and more readily appreciated from the following description of example embodiments, taken in conjunction with the accompanying drawings of which:

FIG. 1 is a block diagram illustrating a sensor device according to some example embodiments;

FIG. 2 is a diagram illustrating a sensor device and a semiconductor manufacturing apparatus according to some example embodiments;

FIG. 3 is a plan view illustrating a sensor device according to some example embodiments;

FIG. 4 is a diagram illustrating a sensor array including a cover according to some example embodiments;

FIG. 5 is a diagram illustrating a sensor array including an insulation material according to some example embodiments;

FIG. 6 is a diagram illustrating a sensor array including a pipeline according to some example embodiments;

FIG. 7 is a diagram illustrating a substrate according to some example embodiments; and

FIG. 8 is a diagram illustrating a flow velocity map according to some example embodiments.

### DETAILED DESCRIPTION

Terms used in example embodiments are selected from currently widely used general terms when possible while considering the functions in the present disclosure. However, the terms may vary depending on the intention of a person skilled in the art, precedents, the emergence of new technology, and the like. Further, in certain cases, there are also terms arbitrarily selected by the applicant, and in these cases, the meaning will be described in detail in the corresponding descriptions. Therefore, the terms used in the present disclosure are not to be construed simply as its designation but based on the meaning of the term and the overall context of the present disclosure.

Throughout the specification, when a part is described as “comprising or including” a component, it does not exclude another component but may further include another component unless otherwise stated. Furthermore, terms such as “. . . unit,” “. . . part,” and “. . . module” described in the specification mean a unit that processes at least one function or operation, which may be implemented as hardware, software, or a combination thereof.

Hereinafter, example embodiments of the present disclosure will be described in detail with reference to the accompanying drawings so that those of ordinary skill in the art to which the present disclosure pertains may easily implement example embodiments of the present disclosure. However, the present disclosure may be implemented in multiple different forms and is not limited to the example embodiments described herein.

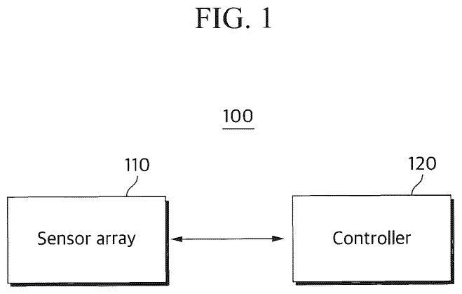

FIG. 1 is a block diagram illustrating a sensor device according to some example embodiments.

Referring to FIG. 1, a sensor device 100 according to some example embodiments may be disposed within a semiconductor manufacturing apparatus. The sensor device 100 may monitor a flow state of a gas within the semiconductor manufacturing apparatus. For example, the flow state of the gas may include at least one of a flow velocity and a movement direction of the gas.

The sensor device 100 may include a sensor array 110 and a controller 120. The sensor array 110 and the controller 120 may transmit and receive information by performing communication. The controller 120 may identify sensing information through the sensor array 110. For example, the controller 120 may control a sensing operation of the sensor array 110 by transmitting a control signal to the sensor array 110. The sensor array 110 may obtain the sensing information by performing the sensing operation. The controller 120 may receive the sensing information from the sensor array 110. In some example embodiments, the number of the sensor array 110 may be one or a plurality.

In some example embodiments, the sensor array 110 may include a plurality of calorimeters.

The calorimeters may identify a thermal state. In some example embodiments, the thermal state may include at least one of an amount of heat transfer, a temperature, and an ambient temperature of the calorimeters. For example, the amount of heat transfer in the calorimeters may include at least one of an amount of heat transferred and introduced into the calorimeters and an amount of heat transferred and released from the calorimeters. The amount of heat transferred and introduced into the calorimeters may represent an amount of heat generated by Joule heating or transferred from other external heat sources to the calorimeters. The amount of heat transferred and released from the calorimeters may represent an amount of heat lost from the calorimeters to an external environment by convection or conduction. For example, the temperature of the calorimeters may be a temperature of a specific portion (for example, a surface) in the calorimeters. For example, the ambient temperature of the calorimeters may be a temperature of the gas within a reference distance from a specific portion (for example, a surface) in the calorimeters.

In some example embodiments, the controller 120 may identify the flow state of the gas based on the thermal state of the plurality of calorimeters. For example, the flow state of the gas may include at least one of a flow velocity and a movement direction of the gas around the sensor array 110.

For example, the controller 120 may identify a pressure of the gas using information on a first calorimeter and identify a flow velocity of the gas using information on a second calorimeter and the pressure. Here, the first calorimeter may be a calorimeter in which an influence of the flow velocity is removed, reduced, and/or minimized.

For another example, the controller 120 may identify an amount of heat transfer by convection using the information on the first calorimeter and the information on the second calorimeter and identify the flow velocity of the gas with accuracy improved using the amount of heat transfer by convection. Here, the information on the first calorimeter may include an amount of heat transfer by conduction, and the information on the second calorimeter may include an amount of heat transfer by conduction and convection.

For another example, the controller 120 may identify a flow velocity in a first direction using the information on the first calorimeter and identify a flow velocity in a second direction using the information on the second calorimeter.

According to some example embodiments of the present disclosure, the sensor device 100 monitoring an internal environment of the semiconductor manufacturing apparatus may be provided. The sensor device 100 according to some example embodiments may be an ultra-precise calorimeter, and may monitor a flow velocity of a gas accurately and efficiently. Hereinafter, some example embodiments of the present disclosure are more specifically described with reference to the accompanying drawings.

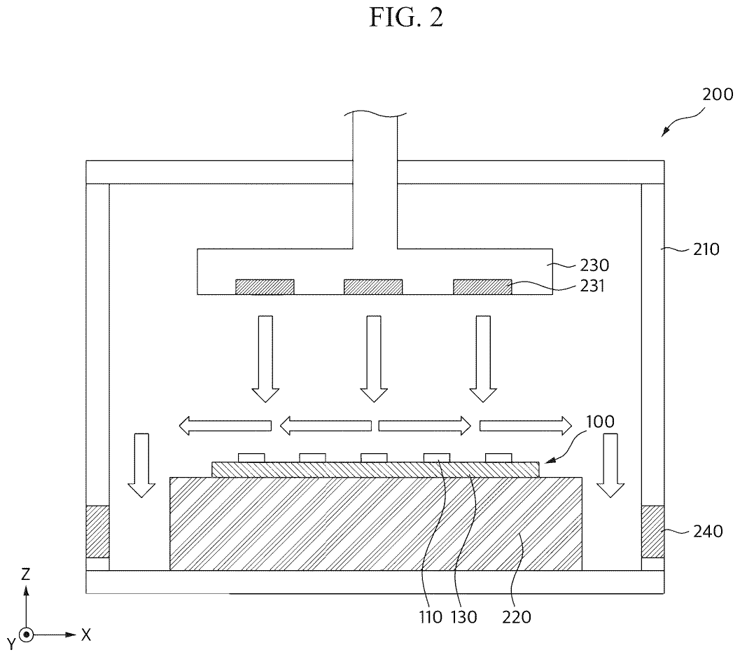

FIG. 2 is a diagram illustrating a sensor device and a semiconductor manufacturing apparatus according to some example embodiments.

Referring to FIG. 2, a semiconductor manufacturing apparatus 200 according to some example embodiments may be an apparatus in which a gas is supplied to an internal space to perform a semiconductor process. For example, the semiconductor process may include at least one of various processes such as chemical vapor deposition (CVD), atomic layer deposition (ALD), physical vapor deposition (PVD), plasma enhanced chemical vapor deposition (PECVD), etching, doping, epitaxial deposition, and/or oxidation processes. The gas may react with a surface of a target substrate where the semiconductor process is performed to induce a chemical and/or physical reaction.

In some example embodiments, the semiconductor manufacturing apparatus 200 may include a chamber 210, a stage 220, a gas supply part 230, and a gas discharge part (or an exhaust part) 240.

The chamber 210 may form the internal space of the semiconductor manufacturing apparatus 200. The internal space may be a space surrounded by the chamber 210. The gas may be injected into the internal space through the gas supply part 230. A target substrate or the sensor device 100 may be seated on the stage 220. The stage 220 may fix a location of the target substrate or the sensor device 100 seated. The gas supply part 230 may supply the gas to the internal space of the semiconductor manufacturing apparatus 200. The gas supply part 230 may include a nozzle 231 through which the gas is injected and a flow control device for controlling the supply of the gas. The gas discharge part 240 may discharge the gas supplied from the gas supply part 230 to an outside. The gas supply part 230 and the gas discharge part 240 may control a flow velocity and/or a pressure of the gas present in the internal space of the semiconductor manufacturing apparatus 200.

The sensor device 100 may be disposed in the semiconductor manufacturing apparatus 200. For example, the sensor device 100 may be disposed on the stage 220. In some example embodiments, the semiconductor manufacturing apparatus 200 may include the sensor device 100.

The sensor device 100 may include the sensor array 110 and the controller 120. The sensor array 110 may be disposed in a flow path of the gas supplied to the semiconductor manufacturing apparatus 200. For example, the gas supply part 230 may be positioned above the sensor device 100 and the gas discharge part 240 may be positioned beside and/or below the sensor device 100. In this case, the gas may flow along a path from the gas supply part 230 through the sensor device 100 to the gas discharge part 240.

In some example embodiments, the sensor device 100 may further include a substrate 130. One or the plurality of sensor arrays 110 may be formed on the substrate 130. In some example embodiments, the controller 120 may be formed on the substrate 130 or formed within the substrate 130.

In some example embodiments, the substrate 130 may be a thin film of which a length in a height direction is very short compared to a length in a horizontal direction. The substrate 130 may have various shapes such as a circle or a quadrilateral in the height direction. The shape of the substrate 130 may be substantially identical to the shape of the target substrate put into the semiconductor manufacturing apparatus 200.

In some example embodiments, the substrate 130 may include various types of wafers. For example, the substrate 130 may include a silicon nitride (SiN) wafer. However, this is merely an example embodiment, and the substrate 130 may include at least one of a silicon (Si) wafer, a gallium arsenide (GaAs) wafer, a sapphire (Al₂O₃) wafer, a germanium (Ge) wafer, a gallium nitride (GaN) wafer, and a silicon carbide (SiC) wafer. However, example embodiments are not limited thereto. In some example embodiments, the substrate 130 may include at least one of a glass substrate, a ceramic substrate, and a printed circuit board. In some example embodiments, the substrate 130 may include an inert material. The inert material may be a material which does not react with the gas.

In some example embodiments, the controller 120 may generate a flow velocity map of the gas. The flow velocity map may include at least one of a flow velocity and a movement direction of an ambient gas for a location of each of the plurality of sensor arrays 110. The controller 120 may transmit the flow velocity map to the semiconductor manufacturing apparatus 200. For this, the sensor device 100 may include a communication circuit that performs wired communication or wireless communication with the semiconductor manufacturing apparatus 200. For example, the wired communication may be at least one of various manners such as Ethernet, serial communication, a universal serial bus (USB), optical fiber communication, and controller area network (CAN) communication. The wireless communication may be at least one of various manners such as Bluetooth, Zigbee, near field communication (NFC), and Long Range (LoRa) communication. However, example embodiments are not limited thereto. The semiconductor manufacturing apparatus 200 may adjust a supply amount of the gas from the gas supply part 230 at a specific location based on the flow velocity map.

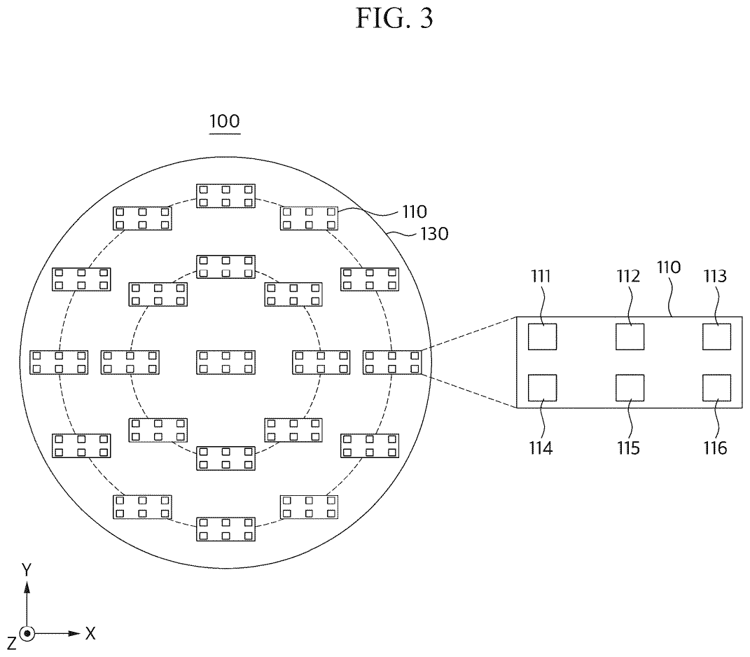

FIG. 3 is a plan view illustrating a sensor device according to some example embodiments.

Referring to FIGS. 1 and 3, the sensor device 100 according to some example embodiments may include the sensor array 110 and the controller 120. The sensor device 100 may further include the substrate 130. In some example embodiments, the sensor device 100 may be implemented in the form of a substrate-type sensor.

One or the plurality of sensor arrays 110 may be formed on the substrate 130. For example, each of the plurality of sensor arrays 110 may be disposed at a location corresponding to a distance and an angle based on a center of the substrate 130 on the substrate 130 according to a polar coordinate system on the substrate 130. As another example, each of the plurality of sensor arrays 110 may be disposed at a location corresponding to a distance in a first direction (for example, an X-axis direction) and a distance in a second direction (for example, a Y-axis direction) on the substrate 130 according to an orthogonal coordinate system.

The sensor array 110 may include a plurality of calorimeters 111 to 116. The plurality of calorimeters 111 to 116 may be disposed to be spaced apart from each other within the sensor array 110. For example, a distance between two calorimeters closest among the plurality of calorimeters 111 to 116 may have a value from several nanometers to several tens of millimeters.

The plurality of calorimeters 111 to 116 may include the first calorimeter 111 to the sixth calorimeter 116. For example, the first calorimeter 111 may be a calorimeter for identifying pressure. For example, the second calorimeter 112 may be a calorimeter for identifying a flow velocity of a gas. For example, the third calorimeter 113 may be a calorimeter for identifying a flow velocity of a gas in a first direction. For example, the fourth calorimeter 114 may be a calorimeter for identifying a flow velocity of a gas in a second direction. For example, the fifth calorimeter 115 may be a calorimeter for identifying an amount of heat transfer by conduction. For example, the sixth calorimeter 116 may be a calorimeter for identifying an ambient temperature of a gas. Meanwhile, this is merely an example embodiment, and the number and use of the plurality of calorimeters 111 to 116 may be variously modified and implemented.

In some example embodiments, at least one of the plurality of calorimeters 111 to 116 may include a temperature sensor identifying a temperature. In some example embodiments, the temperature sensor may include a resistance thermometer. The resistance thermometer may measure temperatures using a characteristic of a material resistance changing depending on temperatures. For example, the temperature sensor may identify a temperature T based on Equation 1 below.

R(T)=R0×[1+α(T−T0)] [Equation 1]

Here, a resistance R(T) is resistance (for example, the unit is ohms (Ω)) at the temperature T (for example, the unit is degrees Celsius (° C.) or kelvins (K)) and may be measured by the temperature sensor. A reference resistance R0 is resistance (for example, the unit is Ω) at a reference temperature T0 (for example, the unit is ° C. or K) and may be stored in the temperature sensor or the controller 120 in advance. A temperature coefficient of resistance α indicates a resistance change rate (for example, the unit is 1 per ° C. (1/° C.) or 1 per K (1/K)) based on a temperature change in a material and may be stored in the temperature sensor or the controller 120 in advance. The temperature coefficient of resistance may have different values depending on materials. The reference temperature T0 may be stored in the temperature sensor or the controller 120 in advance. For example, the reference temperature T0 may be set to 25° C. but may be modified to different values such as 0° C. and implemented. For example, the temperature sensor or the controller 120 may obtain the temperature T by performing an operation based on Equation 1 using the reference resistance R0, the temperature coefficient of resistance α, and the reference temperature T0 stored in advance and the resistance R(T) measured. Meanwhile, the temperature sensor may be implemented in various manners such as a thermocouple measuring temperatures using a voltage difference generated by joining two different metals.

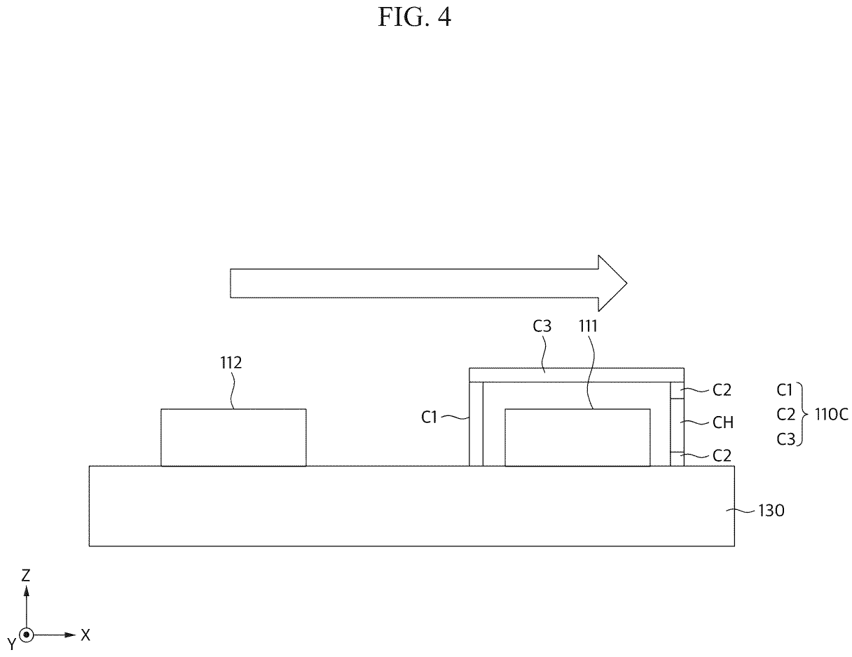

FIG. 4 is a diagram illustrating a sensor array including a cover according to some example embodiments.

Referring to FIG. 4, the sensor array 110 according to some example embodiments may include the plurality of calorimeters 111 and 112. The plurality of calorimeters 111 and 112 may include the first calorimeter 111 and the second calorimeter 112. For example, the first calorimeter 111 may be a calorimeter for identifying pressure. For example, the second calorimeter 112 may be a calorimeter for identifying a flow velocity of a gas. The controller 120 may identify a thermal state of the gas through the plurality of calorimeters 111 and 112 of the sensor array 110.

The controller 120 may identify a pressure of the gas based on a temperature of the first calorimeter 111, an ambient temperature, and a first amount of heat transfer in the first calorimeter 111. Here, the first calorimeter 111 may be disposed in an environment where a flow velocity of the gas is controlled to identify the pressure of the gas. For example, the controller 120 may identify the pressure of the gas using a correlation between the thermal state and the pressure. The controller 120 may identify a flow velocity of the gas based on a temperature of the second calorimeter 112, the ambient temperature, a second amount of heat transfer in the second calorimeter 112, and the pressure. For example, the controller 120 may identify the flow velocity of the gas using a correlation of the thermal state, the pressure, and the flow velocity.

In some example embodiments, the sensor array 110 may further include a cover 110C. The cover 110C may surround at least a portion of the first calorimeter 111. For example, being surrounded by the cover 110C may represent that the cover 110C surrounds the periphery of the first calorimeter 111 while being not in contact (or being in contact) with the first calorimeter 111. The cover 110C may block a flow of the gas within an area measured by the first calorimeter 111. In this case, a flow velocity of the gas within the corresponding area may have a value of 0 or less than a reference value.

In some example embodiments, the cover 110C may include a plurality of partition walls C1 to C3.

The plurality of partition walls C1 to C3 may include the first partition wall C1 and the second partition wall C2. The first partition wall C1 may be disposed in an inflow direction of the gas. The second partition wall C2 may be disposed in an outflow direction of the gas. For example, when the gas is introduced in a −X-axis direction and discharged in a +X-axis direction, the first partition wall C1 may be disposed in the −X-axis direction in a positional relationship with the second partition wall C2, and the second partition wall C2 may be disposed in the +X-axis direction in a positional relationship with the first partition wall C1. An opening CH may be formed at the second partition wall C2. The gas may be introduced into the first calorimeter 111 through the opening CH.

In some example embodiments, the plurality of partition walls C1 to C3 may further include the third partition wall C3. The third partition wall C3 may connect between the first partition wall C1 and the second partition wall C2. For example, the third partition wall C3 may be disposed parallel to a movement direction of the gas. However, this is merely an example embodiment, and the structure of the third partition wall C3 may be variously modified and implemented.

In some example embodiments, the first calorimeter 111 may be disposed in an internal space of the cover 110C. In this case, the first amount of heat transfer in the first calorimeter 111 may include an amount of heat transfer by the pressure of the gas.

In some example embodiments, the second calorimeter 112 may be disposed in an open space where the gas flows based on the flow velocity. In this case, the second amount of heat transfer in the second calorimeter 112 may include the amount of heat transfer by the pressure of the gas and an amount of heat transfer by the flow velocity of the gas.

In some example embodiments, the controller 120 may identify a first heat transfer coefficient based on the first amount of heat transfer, an area, the temperature, and the ambient temperature of the first calorimeter 111. The controller 120 may identify the pressure of the gas based on the first heat transfer coefficient and the ambient temperature. The first heat transfer coefficient may be a value indicating a heat transfer rate between the first calorimeter 111 and an ambient gas. The first heat transfer coefficient may be determined based on characteristics (for example, flow velocity, viscosity, and density) of the ambient gas.

In some example embodiments, the controller 120 may identify a second heat transfer coefficient based on the second amount of heat transfer, an area, the temperature, and the ambient temperature of the second calorimeter 112. The controller 120 may identify the flow velocity of the gas based on the second heat transfer coefficient, the ambient temperature, and the pressure of the gas. The second heat transfer coefficient may be a value indicating a heat transfer rate between the second calorimeter 112 and an ambient gas. The second heat transfer coefficient may be determined based on various characteristics (for example, flow velocity, viscosity, and density) of the ambient gas. However, example embodiments are not limited thereto.

For example, the controller 120 may identify a heat transfer coefficient h based on Equation 2 below. This may be applied to each of the first heat transfer coefficient of the first calorimeter 111 and the second heat transfer coefficient of the second calorimeter 112 described above.

Qconv=h×A×(Ts−Te) [Equation 2]

An amount of heat transfer Qconv may represent an amount (for example, the unit is watts (W) or joules per second (J/s)) of heat transferred between a calorimeter and a gas per unit time. For example, a greater value of the amount of heat transfer Qconv may indicate that more heat is transferred. An area A may represent a surface area (for example, the unit is square meters (m²)) of the calorimeter in which heat transfer occurs. For example, the area A may represent a contact area between the calorimeter and the gas and may be stored in the calorimeter or the controller 120 in advance. As a value of the area A is greater, more heat may be transferred. A temperature Ts may represent a temperature (for example, the unit is ° C. or K) of a surface of the calorimeter. An ambient temperature Te may represent a temperature (for example, the unit is ° C. or K) of an ambient gas of the calorimeter. The ambient temperature Te may be a temperature measured by a separate temperature sensor or measured by the calorimeter before heated according to the manner of Joule heating. The heat transfer coefficient h may be a constant (for example, the unit is watts per square meter per kelvin (W/(m²·K))). In some example embodiments, the amount of heat transfer Qconv may be regarded as substantially identical to an amount of heat transfer that is transferred to the surface of the calorimeter according to the manner of Joule heating.

In some example embodiments, the first calorimeter 111 may include a first resistor. The second calorimeter 112 may include a second resistor. In some example embodiments, the first resistor and the second resistor may generate heat. For example, the first resistor and the second resistor may generate heat according to the manner of Joule heating when a current is supplied. The generated heat may be transferred to the ambient gases through surfaces of the first calorimeter and the second calorimeter. In some example embodiments, the first resistor and the second resistor may include at least one of various metal materials such as nickel and tungsten.

In some example embodiments, the controller 120 may supply the current to the first resistor and the second resistor so that the first calorimeter 111 and the second calorimeter 112 are heated. The controller 120 may identify the first amount of heat transfer based on a resistance of the first resistor and the current. The controller 120 may identify the second amount of heat transfer based on a resistance of the second resistor and the current.

For example, the controller 120 may identify an amount of heat transfer Qh according to a resistance R and a current I based on Equation 3 below. This may be applied to each of the first amount of heat transfer and the second amount of heat transfer described above.

Qh=I²×R [Equation 3]

Here, the amount of heat transfer Qh may be calculated as a value (for example, the unit is W) of multiplying a square of the current I (for example, the unit is amperes (A)) flowing in a resistor of a calorimeter and the resistance R (for example, the unit is Ω) of the resistor. Meanwhile, this is merely an example embodiment, and the amount of heat transfer Qh may be modified as being identified by the calorimeter and implemented. In some example embodiments, when the calorimeter is in a thermal equilibrium state, the amount of heat transfer Qh of Equation 3 and the amount of heat transfer Qconv of Equation 2 may be regarded as substantially identical. For example, the thermal equilibrium state may be a state in which a temperature of a surface of the calorimeter is maintained for a reference time.

In some example embodiments, the controller 120 may determine a temperature identified by the first calorimeter 111 after the first calorimeter 111 is heated as the temperature of the first calorimeter 111. A temperature identified by the second calorimeter 112 after the second calorimeter 112 is heated may be determined as the temperature of the second calorimeter 112.

In some example embodiments, the sensor array 110 may further include a temperature sensor or the third calorimeter 113.

The third calorimeter 113 may be a sensor measuring a thermal state of a type identical to the first calorimeter 111 and the second calorimeter 112, and the temperature sensor may be a sensor measuring a temperature of a type different from the first calorimeter 111 and the second calorimeter 112. For example, the third calorimeter 113 may be a calorimeter only measuring a temperature without Joule heating. For example, the temperature sensor may be a sensor with higher temperature measurement performance than the first calorimeter 111 and the second calorimeter 112.

The temperature sensor (or the third calorimeter 113) may be disposed around the first calorimeter 111 and the second calorimeter 112 to identify temperatures of the ambient gases of the first calorimeter 111 and the second calorimeter 112. For example, the temperature sensor (or the third calorimeter 113) may be disposed between the first calorimeter 111 and the second calorimeter 112. For another example, the temperature sensor (or the third calorimeter 113) may be disposed within a preset radius based on centers of the first calorimeter 111 and the second calorimeter 112.

Meanwhile, this is merely an example embodiment, and the controller 120 may identify the ambient temperature using one of the first calorimeter 111 and the second calorimeter 112.

In some example embodiments, the controller 120 may determine the ambient temperature based on one of the temperature identified by the first calorimeter 111 before the first calorimeter 111 is heated and the temperature identified by the second calorimeter 112 before the second calorimeter 112 is heated.

For example, the controller 120 may determine a latest temperature among temperatures identified by the first calorimeter 111 before the first calorimeter 111 is heated as the ambient temperature. For another example, the controller 120 may determine a latest temperature among temperatures identified by the second calorimeter 112 before the second calorimeter 112 is heated as the ambient temperature. For another example, the controller 120 may determine an average value of the latest temperature identified by the first calorimeter 111 before heated and the latest temperature identified by the second calorimeter 112 before heated as the ambient temperature.

In some example embodiments, the controller 120 may identify the pressure of the gas based on the first heat transfer coefficient of the first calorimeter 111 and the ambient temperature. Here, the first calorimeter 111 may be disposed in an environment where a flow velocity of the gas is controlled to identify the pressure of the gas. For example, the controller 120 may identify a pressure P of the gas based on Equation 4 below.

h1=P^{a}×T^{-b} [Equation 4]

A constant a is an index for pressure and a constant b is an index for temperature. The constants a and b may be preset and may be obtained experimentally. A temperature T may be an ambient temperature of a calorimeter. A first heat transfer coefficient h1 may be a value calculated based on Equation 2. The pressure P may be calculated based on Equation 4.

In some example embodiments, the controller 120 may identify the flow velocity of the gas based on the second heat transfer coefficient of the second calorimeter 112, the ambient temperature, and the pressure of the gas. For example, the controller 120 may identify a flow velocity v of the gas based on Equation 5 below.

h2=P^{a}×T^{-b}×vⁿ [Equation 5]

A constant a is an index for pressure, a constant b is an index for temperature, and a constant n is an index for flow velocity. The constants a, b, and n may be preset and may be obtained experimentally. A temperature T may be an ambient temperature of a calorimeter. A second heat transfer coefficient h2 may be a value calculated based on Equation 2. The pressure P may be a value calculated based on Equation 4. The flow velocity v of the gas may be calculated based on Equation 5.

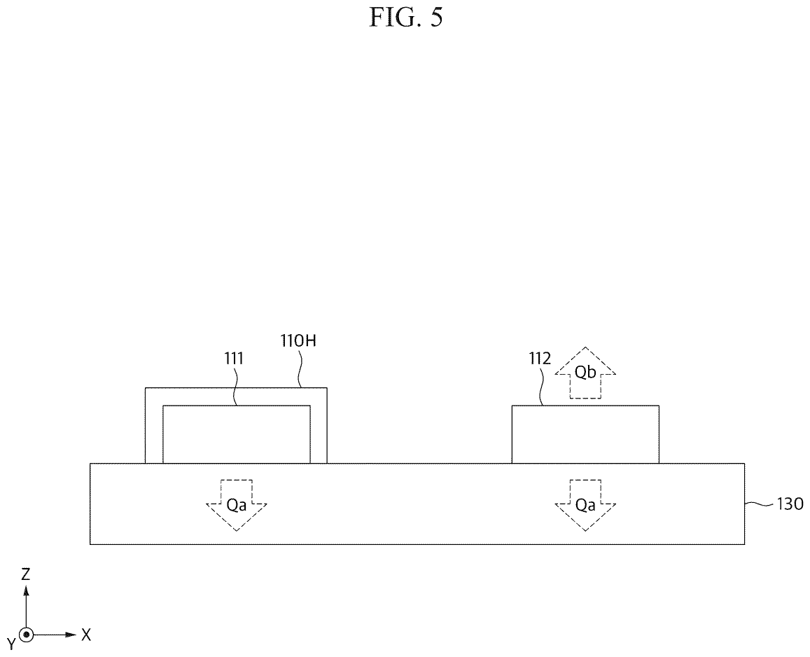

FIG. 5 is a diagram illustrating a sensor array including an insulation material according to some example embodiments.

Referring to FIG. 5, the sensor array 110 may include the first calorimeter 111 and the second calorimeter 112.

In some example embodiments, the sensor array 110 may further include an insulation material 110H covering the first calorimeter 111. In some example embodiments, the insulation material 110H may be molded on an upper surface of the first calorimeter 111. In other words, the insulation material 110H may cover a surface of the first calorimeter 111 so that the first calorimeter 111 has no exposed portion. The insulation material 110H may include a material having insulation performance, of which heat conductivity is less than a reference value. For example, the material having insulation performance may include one of various materials such as glass wool, ceramic fiber, aerogel, and polyurethane foam. However, example embodiments are not limited thereto. The insulation material 110H may block, reduce, and/or minimize heat transfer through convection in the first calorimeter 111.

The controller 120 may identify a first amount of heat transfer in the first calorimeter 111 and a second amount of heat transfer in the second calorimeter 112. In some example embodiments, heat transfer by Joule heating and conduction may occur in the first calorimeter 111, and heat transfer by Joule heating, conduction, and convection may occur in the second calorimeter 112. In other words, the first calorimeter 111 may be a calorimeter for identifying an amount of heat transfer by conduction.

In this case, the controller 120 may correct the second amount of heat transfer based on a difference value between the first amount of heat transfer in the first calorimeter 111 and the second amount of heat transfer in the second calorimeter 112.

In some example embodiments, the corrected second amount of heat transfer may be the difference value between the first amount of heat transfer and the second amount of heat transfer. For example, the first amount of heat transfer in the first calorimeter 111 may be a value of subtracting an amount Qa of heat transfer by conduction from an amount of heat transfer by Joule heating. For example, the second amount of heat transfer in the second calorimeter 112 may be a value of subtracting the amount Qa of heat transfer by conduction and an amount Qb of heat transfer by convection from the amount of heat transfer by Joule heating. Here, the difference value between the first amount of heat transfer and the second amount of heat transfer may be the amount Qb of heat transfer by convection. In this case, since the corrected second amount of heat transfer uses a difference between the first amount of heat transfer and the second amount of heat transfer, the amount of heat transfer by conduction and a noise component may be removed together. In other words, the corrected second amount of heat transfer may include the amount Qb of heat transfer by convection alone. According to some example embodiments of the present disclosure, the amount of heat transfer by conduction may be reduced and/or minimized, and thus, a flow velocity of a gas may be accurately measured.

In addition, the controller 120 may identify the flow velocity of the gas based on the corrected second amount of heat transfer in the second calorimeter 112, a temperature of the second calorimeter 112, an ambient temperature, and a pressure of the gas. For example, based on Equation 2, the controller 120 may identify a second heat transfer coefficient based on the corrected second amount of heat transfer, an area, the temperature, and the ambient temperature of the second calorimeter 112. Based on Equation 5, the controller 120 may identify the flow velocity of the gas based on the second heat transfer coefficient, the ambient temperature, and the pressure of the gas. The pressure of the gas may be obtained using the third calorimeter 113 for identifying pressure described below or a separate pressure sensor.

In some example embodiments, the sensor array 110 may further include the third calorimeter 113 and a cover. The cover may surround at least a portion of the third calorimeter 113. The cover may be the cover 110C described above in the description of FIG. 4.

In this case, based on a difference value between the first amount of heat transfer in the first calorimeter 111 and a third amount of heat transfer in the third calorimeter 113, the controller 120 may correct the third amount of heat transfer. In some example embodiments, heat transfer by Joule heating and conduction may occur in the first calorimeter 111, and heat transfer by Joule heating, conduction, and convection may occur in the third calorimeter 113. In some example embodiments, the corrected third amount of heat transfer may be the difference value between the first amount of heat transfer and the third amount of heat transfer.

In addition, the controller 120 may identify the pressure based on the corrected third amount of heat transfer, a temperature of the third calorimeter 113, and an ambient temperature. For example, based on Equation 2, the controller 120 may identify a third heat transfer coefficient based on the corrected third amount of heat transfer, an area, the temperature, and the ambient temperature of the third calorimeter 113. Based on Equation 4, the controller 120 may identify the pressure of the gas based on the third heat transfer coefficient and the ambient temperature.

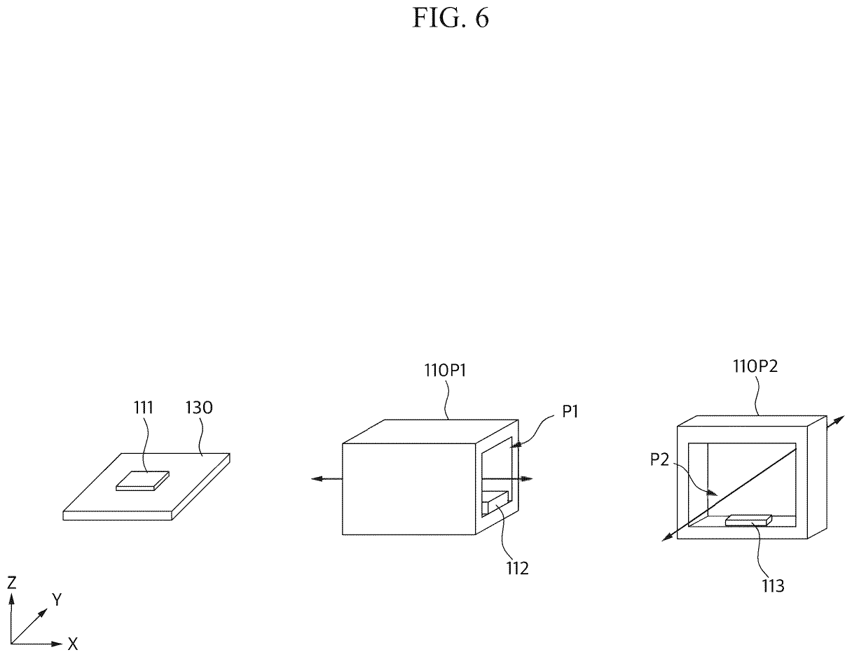

FIG. 6 is a diagram illustrating a sensor array including a pipeline according to some example embodiments.

Referring to FIG. 6, the sensor array 110 may include the plurality of calorimeters 111 to 113. The plurality of calorimeters 111 to 113 may include the first calorimeter 111, the second calorimeter 112, and the third calorimeter 113.

For example, the first calorimeter 111 may be a calorimeter for identifying a flow velocity of a gas. The second calorimeter 112 may be a calorimeter for identifying a flow velocity of a gas in a first direction (for example, the X-axis direction). The third calorimeter 113 may be a calorimeter for identifying a flow velocity of a gas in a second direction (for example, the Y-axis direction). In other words, the second calorimeter 112 and the third calorimeter 113 may be a calorimeter for measuring gas directionality. Here, at least one of the first calorimeter 111 to the third calorimeter 113 may be omitted.

In some example embodiments, the sensor array 110 may further include a first pipeline 110P1.

The first pipeline 110P1 may form a flow path P1 in the first direction. In other words, the first pipeline 110P1 may be a structure that induces a gas to flow in the first direction along the flow path P1. For example, the first direction may be a first horizontal direction (for example, the X-axis direction). The second calorimeter 112 may be disposed within the flow path P1 of the first pipeline 110P1. In this case, the controller 120 may identify a flow velocity of the gas based on a temperature of the second calorimeter 112, an ambient temperature, a second amount of heat transfer, and a pressure. The controller 120 may identify (or determine) the identified flow velocity as a flow velocity of the gas in the first direction. For example, the controller 120 may identify the flow velocity of the gas in the first direction based on Equation 5. The pressure of the gas may be obtained using a calorimeter for identifying pressure or a separate pressure sensor.

In some example embodiments, the sensor array 110 may further include a second pipeline 110P2.

The second pipeline 110P2 may form a flow path P2 in the second direction. The second direction may be a direction different from the first direction. For example, the second direction may be a direction perpendicular to the first direction. For example, the second direction may be a second horizontal direction (for example, the Y-axis direction). In other words, the second pipeline 110P2 may be a structure that induces the gas to flow in the second direction along the flow path P2. The third calorimeter 113 may be disposed within the flow path P2 of the second pipeline 110P2. In this case, the controller 120 may identify a flow velocity of the gas based on a temperature of the third calorimeter 113, an ambient temperature, a third amount of heat transfer, and the pressure. The controller 120 may identify (or determine) the identified flow velocity as a flow velocity in the second direction. For example, the controller 120 may identify the flow velocity of the gas in the second direction based on Equation 5. The pressure of the gas may be obtained using a calorimeter for identifying pressure or a separate pressure sensor.

In some example embodiments, for the first calorimeter 111 exposed externally without a separate structure, the controller 120 may identify the flow velocity of the gas based on a temperature of the first calorimeter 111, an ambient temperature, a first amount of heat transfer, and the pressure. In this case, the flow velocity of the gas may be measured not based on directionality but based on a magnitude (or a value) alone.

Meanwhile, a cross-sectional shape of the flow path P1 in the first direction (for example, the X-axis direction) and the flow path P2 in the second direction (for example, the Y-axis direction) is illustrated as a quadrilateral, which is merely an example embodiment, but may be modified and implemented as a polygon such as triangle and pentagon or a shape including a curve such as circle and ellipse. However, example embodiments are not limited thereto.

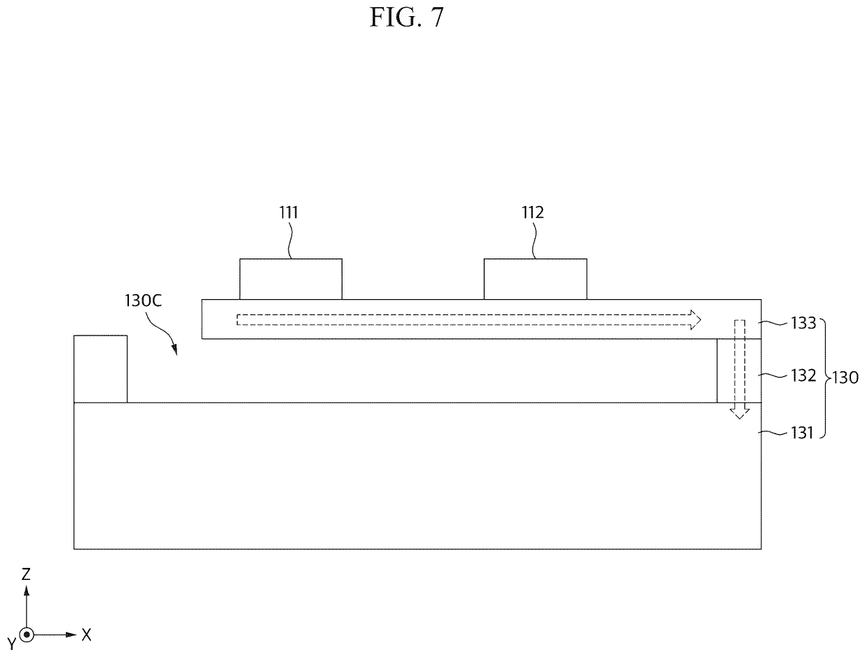

FIG. 7 is a diagram illustrating a substrate according to some example embodiments.

Referring to FIG. 7, the sensor device 100 according to some example embodiments may include the sensor array 110 and the controller 120. The sensor device 100 may further include the substrate 130.

The substrate 130 may include a base part 131 and a support part 133. The substrate 130 may further include a connection part 132.

The support part 133 may be formed above the base part 131. A cavity 130C may be formed between the base part 131 and the support part 133. For example, the base part 131 may be a portion supporting other structures (for example, the connection part 132 and the support part 133). The connection part 132 may be a portion connecting the base part 131 and the support part 133. The support part 133 may be a portion corresponding to a surface of the substrate 130. The cavity 130C may reduce (and/or minimize) heat transfer by conduction within the substrate 130. In other words, heat may not be transferred from the support part 133 directly to the substrate 130 due to the cavity 130C, and heat may be transferred along a path from the support part 133 to the connection part 132 to the base part 131.

The sensor array 110 may include the first calorimeter 111 and the second calorimeter 112. The first calorimeter 111 and the second calorimeter 112 may be disposed on the support part 133.

In some example embodiments, the sensor array 110 may further include the third calorimeter 113 disposed on the support part 133 and an insulation material covering a surface of the third calorimeter 113. Here, the insulation material may be the insulation material 110H described above in the description of FIG. 5.

In this case, the controller 120 may identify a third amount of heat transfer between the surface of the third calorimeter 113 and the support part 133. The controller 120 may, based on a difference value between a first amount of heat transfer in the first calorimeter 111 and the third amount of heat transfer, correct the first amount of heat transfer. In some example embodiments, the corrected first amount of heat transfer may be the difference value between the first amount of heat transfer and the third amount of heat transfer. The controller 120 may, based on a difference value between a second amount of heat transfer in the second calorimeter 112 and the third amount of heat transfer, correct the second amount of heat transfer. In some example embodiments, the corrected second amount of heat transfer may be the difference value between the second amount of heat transfer and the third amount of heat transfer. Here, the corrected first amount of heat transfer and the corrected second amount of heat transfer may include an amount of heat transfer by convection alone.

The sensor device 100 according to some example embodiments may include the substrate 130, the plurality of sensor arrays 110, and the controller 120. In some example embodiments, the substrate 130 may include the base part 131 and a plurality of the support parts 133. The plurality of sensor arrays 110 may be disposed on the plurality of the support parts 133.

Each of the sensor arrays 110 may include the first calorimeter 111 and the second calorimeter 112. The sensor array 110 may include a first pipeline forming a flow path in a first direction and a second pipeline forming a flow path in a second direction different from the first direction. The first calorimeter 111 may be disposed within the first pipeline and the second calorimeter 112 may be disposed within the second pipeline. Here, the first pipeline and the second pipeline may be the first pipeline 110P1 and the second pipeline 110P2 described above in the description of FIG. 6.

The controller 120 may identify a flow velocity in the first direction (for example, the X-axis direction) based on a temperature of the first calorimeter 111, an ambient temperature, the first amount of heat transfer, and a pressure of a gas. The controller 120 may identify a flow velocity in the second direction (for example, the Y-axis direction) based on a temperature of the second calorimeter 112, the ambient temperature, the second amount of heat transfer, and the pressure of the gas. The controller 120 may identify a flow velocity map. The flow velocity map may include the flow velocity in the first direction (for example, the X-axis direction) and the flow velocity in the second direction (for example, the Y-axis direction) for a location of each of the plurality of sensor arrays 110.

In some example embodiments, the sensor array 110 may further include a pressure sensor identifying the pressure of the gas. The pressure sensor may be a sensor of a type different from a calorimeter. The pressure sensor may be implemented as various types of pressure sensors such as a piezoresistive pressure sensor and a capacitance pressure sensor.

In some example embodiments, the controller 120 may transmit the flow velocity map to the semiconductor manufacturing apparatus 200 to adjust the flow velocity of the gas supplied in the semiconductor manufacturing apparatus 200. The semiconductor manufacturing apparatus 200 may adjust a supply amount of the gas supplied to a specific location based on the flow velocity map. For example, the semiconductor manufacturing apparatus 200 may select a specific location with lower flow velocity than other locations based on the flow velocity map and increase a supply amount of the gas supplied to the selected location. For another example, the semiconductor manufacturing apparatus 200 may select a specific location with higher flow velocity than other locations based on the flow velocity map and decrease a supply amount of the gas supplied to the selected location. By adjusting the flow velocity based on the result of the flow velocity map, the uniformity of the gas distributed inside the semiconductor manufacturing apparatus 200 may be improved. Accordingly, a semiconductor device manufactured in the semiconductor manufacturing apparatus 200 may have improved reliability and/or electrical characteristics.

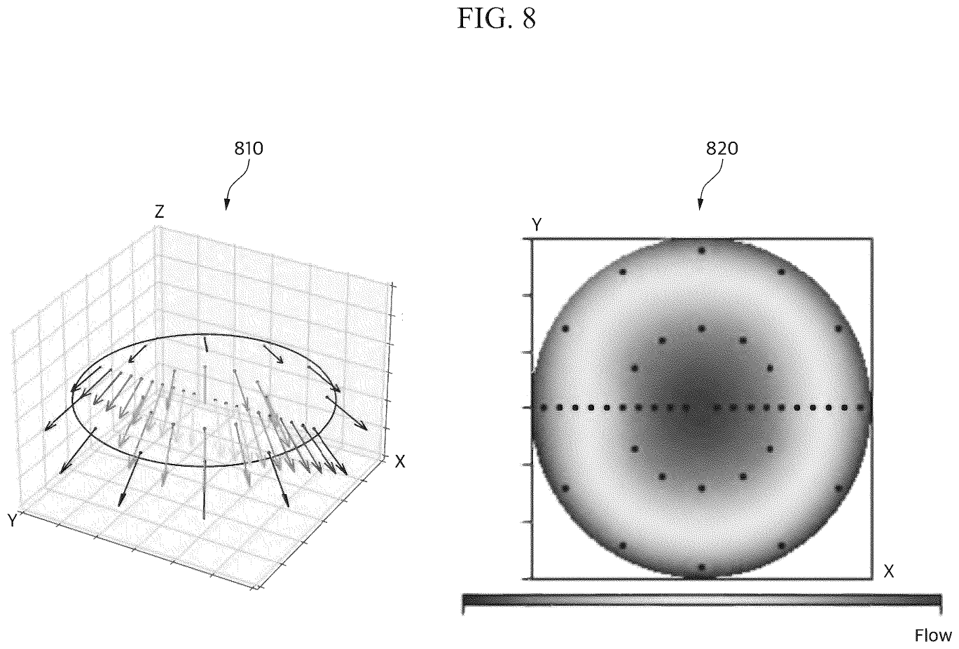

FIG. 8 is a diagram illustrating a flow velocity map according to some example embodiments.

Referring to FIG. 8, a flow velocity map may be generated in various forms of data.

In some example embodiments, a first flow velocity map 810 may be generated as a flow velocity map of a three-dimensional coordinate system. The first flow velocity map 810 may represent a flow velocity and a movement direction of a gas for each location through an arrow on a space of X, Y, and Z axes. For example, a direction of each arrow may represent in which direction a gas moves at a corresponding location, and a length of the arrow may represent a flow velocity magnitude.

In some example embodiments, a second flow velocity map 820 may be generated as a flow velocity map of a two-dimensional coordinate system. The second flow velocity map 820 may represent a flow velocity magnitude of a gas for each location through a color or shading for each location. However, the form of the flow velocity map described above is merely an example embodiment and may be variously modified and implemented.

The sensor device 100 and/or the semiconductor manufacturing apparatus 200 according to the above-described example embodiments may include a processor, a memory for storing and executing program data, a permanent storage such as a disk drive, a communication port that communicates with an external device, and a user interface device such as a touch panel, a key, and a button. Methods implemented as software modules or algorithms may be stored in a computer-readable recording medium as computer-readable codes or program instructions executable on the processor. Here, the computer-readable recording medium includes a magnetic storage medium (for example, read-only memory (ROM), random-access memory (RAM), floppy disks, and hard disks) and an optically readable medium (for example, CD-ROM and digital versatile discs (DVDs)). The computer-readable recording medium may be distributed among network-connected computer systems, so that the computer-readable codes may be stored and executed in a distributed manner. The medium may be readable by a computer, stored in a memory, and executed on a processor.

The example embodiments may be represented by functional block elements and various processing steps. The functional blocks may be implemented in any number of hardware and/or software configurations that perform specific functions. For example, some example embodiments may adopt integrated circuit configurations, such as memory, processing, logic, and/or look-up table, which may execute various functions by the control of one or more microprocessors or other control devices. Similarly to that elements may be implemented as software programming or software elements, some example embodiments may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, some example embodiments may adopt the existing art for electronic environment setting, signal processing, and/or data processing. Terms such as “mechanism,” “element,” “means,” and “configuration” may be used broadly and are not limited to mechanical and physical configurations. The terms may include the meaning of a series of routines of software in association with a processor or the like.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The above-described example embodiments are merely examples, and other example embodiments may be implemented within the scope of the claims to be described later.

What is claimed is:

1. A sensor device for use in a semiconductor manufacturing apparatus, the sensor device comprising:
a sensor array configured to be in a flow path of a gas supplied to the semiconductor manufacturing apparatus, the sensor array including a first calorimeter and a second calorimeter; and
a controller configured to
identify a pressure of the gas based on
a temperature of the first calorimeter,
an ambient temperature, and
a first amount of heat transfer in the first calorimeter, and
identify a flow velocity of the gas based on
a temperature of the second calorimeter,
the ambient temperature,
a second amount of heat transfer in the second calorimeter, and
the pressure.

2. The sensor device of claim 1, wherein
the sensor array further includes a cover configured to surround at least a portion of the first calorimeter, and
the cover includes a first partition wall in an inflow direction of the gas and a second partition wall in an outflow direction of the gas, the first partition wall and the second partition wall defining an opening.

3. The sensor device of claim 2, wherein the second calorimeter is in an open space where the gas flows based on the flow velocity.

4. The sensor device of claim 1, wherein the controller is configured to
identify a first heat transfer coefficient based on
the first amount of heat transfer,
an area of the first calorimeter,
the temperature of the first calorimeter, and
the ambient temperature, and
identify the pressure based on the first heat transfer coefficient and the ambient temperature.

5. The sensor device of claim 4, wherein the controller is configured to identify a second heat transfer coefficient based on
the second amount of heat transfer,
an area of the second calorimeter,
the temperature of the second calorimeter, and
the ambient temperature, and identify the flow velocity based on
the second heat transfer coefficient,
the ambient temperature, and
the pressure.

6. The sensor device of claim 1, further comprising:
a substrate including a base part;
a support part above the base part; and
a cavity is defined by an area between the base part and the support part,
wherein the first calorimeter and the second calorimeter are on the support part.

7. The sensor device of claim 6, wherein
the sensor array further includes
a third calorimeter on the support part and an insulation material configured to cover a surface of the third calorimeter, and
the controller is configured to
identify a third amount of heat transfer between the surface of the third calorimeter and the support part;
generate a corrected first amount by correcting the first amount of heat transfer based on a difference value between the first amount of heat transfer and the third amount of heat transfer; and
generate a corrected second amount by correcting the second amount of heat transfer based on a difference value between the second amount of heat transfer and the third amount of heat transfer.

8. The sensor device of claim 1, wherein
the first calorimeter includes a first resistor,
the second calorimeter includes a second resistor, and
the controller is configured to
supply a current to the first resistor and the second resistor to heat the first calorimeter and the second calorimeter;
identify the first amount of heat transfer based on a resistance of the first resistor and the current; and
identify the second amount of heat transfer based on a resistance of the second resistor and the current.

9. The sensor device of claim 8, wherein
the controller is configured to
determine a temperature of the first calorimeter after the first calorimeter is heated, and
determine a temperature of the second calorimeter after the second calorimeter is heated.

10. The sensor device of claim 8, wherein the sensor array further includes a temperature sensor configured to identify an ambient temperature of a third calorimeter.

11. The sensor device of claim 8, wherein the controller is configured to determine the ambient temperature based on one or more of a temperature of the first calorimeter before the first calorimeter is heated and a temperature of the second calorimeter before the second calorimeter is heated.

12. The sensor device of claim 1, wherein
the sensor array further includes
a first pipeline configured to define a flow path in a first direction, and
a third calorimeter within the flow path of the first pipeline, and
the controller is configured to identify a flow velocity in the first direction based on
a temperature of the third calorimeter,
an ambient temperature,
a third amount of heat transfer in the third calorimeter, and
the pressure.

13. The sensor device of claim 12, wherein
the sensor array further includes
a second pipeline configured to define a flow path in a second direction, the second direction different from the first direction, and
a fourth calorimeter configured to be within the flow path of the second pipeline, and
the controller is configured to
identify a flow velocity in the second direction based on
a temperature of the fourth calorimeter,
an ambient temperature,
a fourth amount of heat transfer in the fourth calorimeter, and
the pressure.

14. The sensor device of claim 1, wherein
the sensor array further includes a first pipeline configured to define a flow path in a first direction,
the second calorimeter is configured to be within the flow path of the first pipeline, and
the controller is configured to identify a flow velocity in the first direction.

15. A sensor device for use within a semiconductor manufacturing apparatus to which a gas is supplied, the sensor device comprising:
a sensor array including
a first calorimeter,
a second calorimeter, and
an insulation material configured to cover the first calorimeter; and
a controller configured to
identify a first amount of heat transfer in the first calorimeter and a second amount of heat transfer in the second calorimeter,
generate a corrected second amount by correcting the second amount of heat transfer based on a difference value between the first amount of heat transfer and the second amount of heat transfer, and
identify a flow velocity of a gas based on the corrected second amount of heat transfer, a temperature of the second calorimeter, an ambient temperature, and a pressure of the gas.

16. The sensor device of claim 15, wherein
the sensor array further includes a third calorimeter and a cover configured to surround at least a portion of the third calorimeter, and
the controller is configured to
identify a third amount of heat transfer in the third calorimeter,
generate a corrected third amount by correcting the third amount of heat transfer based on a difference value between the first amount of heat transfer and the third amount of heat transfer, and
identify the pressure based on
the corrected third amount of heat transfer,
a temperature of the third calorimeter, and
an ambient temperature.

17. The sensor device of claim 15, further comprising:
a substrate including a base part and a support part above the base part; and
a cavity is defined by an area between the base part and the support part,
wherein the first calorimeter and the second calorimeter are on the support part.

18. A sensor device for use within a semiconductor manufacturing apparatus to which a gas is supplied, the sensor device comprising:
a substrate including a plurality of support parts;
a plurality of sensor arrays on the plurality of support parts;
each of the plurality of sensor arrays including
a first pipeline configured to define a flow path in a first direction;
a first calorimeter within the first pipeline;
a second pipeline configured to define a flow path in a second direction, the second direction different from the first direction; and
a second calorimeter within the second pipeline; and
a controller configured to
identify a flow velocity in the first direction based on
a temperature of the first calorimeter,
an ambient temperature,
a first amount of heat transfer, and
a pressure of the gas,
identify a flow velocity in the second direction based on
a temperature of the second calorimeter,
the ambient temperature,
a second amount of heat transfer, and
the pressure of the gas, and
generate a flow velocity map based on
the flow velocity in the first direction and the flow velocity in the second direction for a location of each of the plurality of sensor arrays.

19. The sensor device of claim 18, wherein each of the plurality of sensor arrays further includes a pressure sensor configured to identify the pressure of the gas.

20. The sensor device of claim 18, wherein the controller is configured to transmit the flow velocity map to the semiconductor manufacturing apparatus to adjust a flow velocity of the gas supplied in the semiconductor manufacturing apparatus.
